(19) United States
(12) Patent Application Publication
(10) Pub. No.: US 2025/0241065 A1
(43) Pub. Date: Jul. 24, 2025

(54) TILED DISPLAY PANEL AND DISPLAY DEVICE

(71) Applicant: CHENGDU VISTAR OPTOELECTRONICS CO., LTD., Chengdu (CN)

(72) Inventors: Zhenli SONG, Chengdu (CN); Xiuqi HUANG, Chengdu (CN); Shangjun XU, Chengdu (CN); Fujian REN, Chengdu (CN); Xuan CAO, Chengdu (CN); Shan GAO, Chengdu (CN); Daipeng XING, Chengdu (CN); Wenqian LI, Chengdu (CN)

(73) Assignee: CHENGDU VISTAR OPTOELECTRONICS CO., LTD., Chengdu (CN)

(21) Appl. No.: 19/175,033

(22) Filed: Apr. 10, 2025

Related U.S. Application Data
(63) Continuation of application No. PCT/CN2023/120559, filed on Sep. 22, 2023.

(30) Foreign Application Priority Data
Oct. 26, 2022 (CN) 202211321449.9

(51) Int. Cl. H10D 86/40; H05K 1/18; H10D 86/60

(52) U.S. Cl. CPC H10D 86/441; H05K 1/189; H10D 86/60; H05K 2201/10128

(57) ABSTRACT

A tiled display panel includes at least one tiled unit. Each of the at least one tiled unit includes two sub-display panels tiled in a first direction. Each of the two sub-display panels includes at least two binding portions and at least one signal line. The at least two binding portions are respectively located at two ends of the same sub-display panel in the first direction. The at least one signal line is configured to connect the binding portions located at the two ends of the same sub-display panel. The binding portions located at two ends of each of the at least one tiled unit in the first direction are configured to bind a chip on film.

### CROSS-REFERENCE TO RELATED APPLICATION(S)

This is a continuation of International Patent Application No. PCT/CN2023/120559, filed Sep. 22, 2023, which claims priority to Chinese Patent Application No. 202211321449.9, filed with the China National Intellectual Property Administration (CNIPA) on Oct. 26, 2022, the disclosure of which is incorporated herein by reference in its entirety.

### TECHNICAL FIELD

The present application relates to the field of display technologies, for example, a tiled display panel and a display device.

### BACKGROUND

With the development of display technologies, a tiled display screen has received widespread attention. The pixel transferring sequences of the tiled display screen in the existing technology are inconsistent; therefore, the driving difficulty of the tiled display panel is relatively high.

### SUMMARY

The present application provides a tiled display panel and a display device to solve the problem that the driving difficulty of the tiled display panel is relatively high due to inconsistent pixel transferring sequences of the tiled display screen in the existing technology.

According to an aspect of the present application, a tiled display panel is provided. The tiled display panel includes at least one tiled unit. Each of the at least one tiled unit includes two sub-display panels tiled in a first direction. Each of the two sub-display panels includes at least two binding portions and at least one signal line. The at least two binding portions are respectively located at two ends of the same sub-display panel in the first direction. The at least one signal line is configured to connect the binding portions located at the two ends of the same sub-display panel. Binding portions located at two ends of each of the at least one tiled unit in the first direction are configured to bind a chip on film.

According to another aspect of the present application, a display device is provided. The display device includes the tiled display panel described in the preceding aspect of the present application. The display device further includes a substrate. The substrate includes an open slot. The chip on film is disposed within the open slot.

According to the technical solutions of the embodiments of the present application, each tiled unit includes the two sub-display panels tiled in the first direction, the sub-display panel includes the at least two binding portions, and the at least two binding portions are respectively located at two ends of each sub-display panel in the first direction. The at least one signal line is configured to connect the binding portions located at the two ends of the same sub-display panel, and the binding portions located at two ends of each of the at least one tiled unit in the first direction are configured to bind the chip on film, so that the multiple sub-display panels within the same tiled unit do not need to be rotated, thereby facilitating the consistent pixel arrangement sequences of the tiled multiple sub-display panels, facilitating driving the multiple sub-display panels of the same tiled unit by using the same driving method, reducing the driving difficulty of the tiled display panel, and improving the display effect of the tiled display panel.

### BRIEF DESCRIPTION OF DRAWINGS

FIG. 1 is a schematic structural diagram of a tiled display panel according to an embodiment of the present application;

FIG. 2 is a schematic structural diagram of another tiled display panel according to an embodiment of the present application;

FIG. 3 is a schematic sectional view taken along an AA′ direction of a tiled display panel of FIG. 1 according to an embodiment of the present application;

FIG. 4 is a schematic structural diagram of yet another tiled display panel according to an embodiment of the present application;

FIG. 5 is a schematic structural diagram of yet another tiled display panel according to an embodiment of the present application;

FIG. 6 is a schematic structural diagram of yet another tiled display panel according to an embodiment of the present application;

FIG. 7 is a schematic structural diagram of a display device according to an embodiment of the present application; and

FIG. 8 is a schematic structural diagram of a glass substrate of a display device according to an embodiment of the present application.

### DETAILED DESCRIPTION

The problem that the driving difficulty of the tiled display panel is relatively high due to inconsistent pixel transferring sequences exists between multiple tiled sub-display panels of a tiled display screen. For example, when a 2*N tiled architecture is achieved, since the tiled display screen is tiled, if a binding position is set at an edge, the screen body needs to be rotated by 180°, so that pixel arrangement orders of two tiled display screens are reversed, thereby resulting in the relatively high difficulty in driving the tiled display panel and affecting the display effect of the tiled display panel.

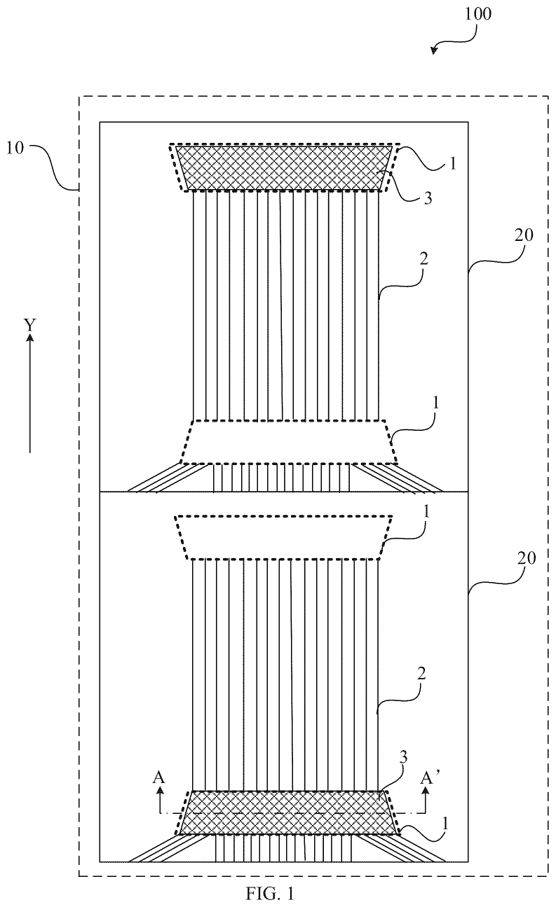

FIG. 1 is a schematic structural diagram of a tiled display panel according to an embodiment of the present application. Referring to FIG. 1, the tiled display panel 100 provided in this embodiment includes at least one tiled unit 10. The tiled unit 10 includes two sub-display panels 20 tiled in a first direction Y. The sub-display panel 20 includes at least two binding portions 1 and at least one signal line 2. The at least two binding portions 1 are respectively located at two ends of the same sub-display panel in the first direction Y. The at least one signal line 2 is configured to connect the binding portions 1 located at the two ends of the same sub-display panel 20. The binding portions 1 located at two ends of each tiled unit 10 in the first direction Y are configured to bind a chip on film 3.

The sub-display panels 20 may be driven and controlled independently of each other. The binding portions 1 of the sub-display panel 20 tiled in the first direction Y are respectively located at two ends of the sub-display panel 20, so that the binding is performed on the binding portion 1 of the sub-display panel 20 facing away from the tiled end as required. When the sub-display panels 20 are tiled, the sub-display panel 20 participating in the tiling does not need to be rotated by a preset angle, thereby ensuring that an edge position of the tiled unit 10 is provided with the binding portion 1 for binding the chip on film 3.

The binding portions 1 located at the two ends of the same sub-display panel 20 are connected through the signal line 2, so that the binding portion 1 binding the chip on film 3 is connected to the binding portion 1, without binding the chip on film 3, of the sub-display panel 20 where the binding portion 1 is located through the signal line 2, in this manner, any one binding portion of the binding portions 1 located at the two ends of the same sub-display panel 20 is bound with the chips on film 3, and the drive signal may be transmitted to the sub-display panel 20.

In the first direction Y, the binding portions 1 located at the two ends of the tiled unit 10 are configured to bind the chip on film 3 to bind the chip on film 3 at the edge position of the tiled unit 10. In order to reduce a thickness of the display device, a space for accommodating the chip on film 3 bound to the binding portion 1 needs to be disposed at the edge position of the tiled unit 10. For example, it is necessary to provide an open slot on a glass substrate of a box body and at a position corresponding to the chip on film 3 bound to the binding portion 1. The binding portions 1 located at the two ends of the tiled unit 10 in the first direction Y are configured to bind the chip on film 3, so that the open slot is provided at the edge position of the glass substrate 4 of the box body, which is conducive to enhancing the mechanical strength of the glass substrate 4 of the box body.

It is to be noted that, FIG. 1 exemplarily shows a case that the tiled display panel 100 includes one tiled unit 10, and the number of tiled units 10 included in the tiled display panel 100 may be set as required, which is not limited herein.

According to the tiled display panel 100 provided in this embodiment, each tiled unit 10 is disposed to include the two sub-display panels 20 tiled in the first direction Y, the sub-display panel 20 is disposed to include at least two binding portions 1, and the at least two binding portions 1 are respectively located at two ends of the sub-display panels 20 in the first direction. The at least one signal line 2 is configured to connect the binding portions 1 located at the two ends of the same sub-display panel 20, and the binding portions 1 located at two ends of each of the at least one tiled unit 10 in the first direction Y are configured to bind the chip on film 3, so that the multiple sub-display panels 20 within the same tiled unit 10 do not need to be rotated, thereby facilitating the consistent pixel arrangement sequence of the tiled multiple sub-display panels 20, facilitating driving the multiple sub-display panels 20 of the same tiled unit 10 by using the same driving method, reducing the driving difficulty of the tiled display panel 100, and improving the display effect of the tiled display panel 100.

It is to be noted that FIG. 1 only exemplarily shows a setting manner in the first direction Y. The first direction Y proposed in this embodiment may be a direction of gravity, or a direction intersecting with the direction of gravity, such as a direction perpendicular to gravity, which is not limited herein.

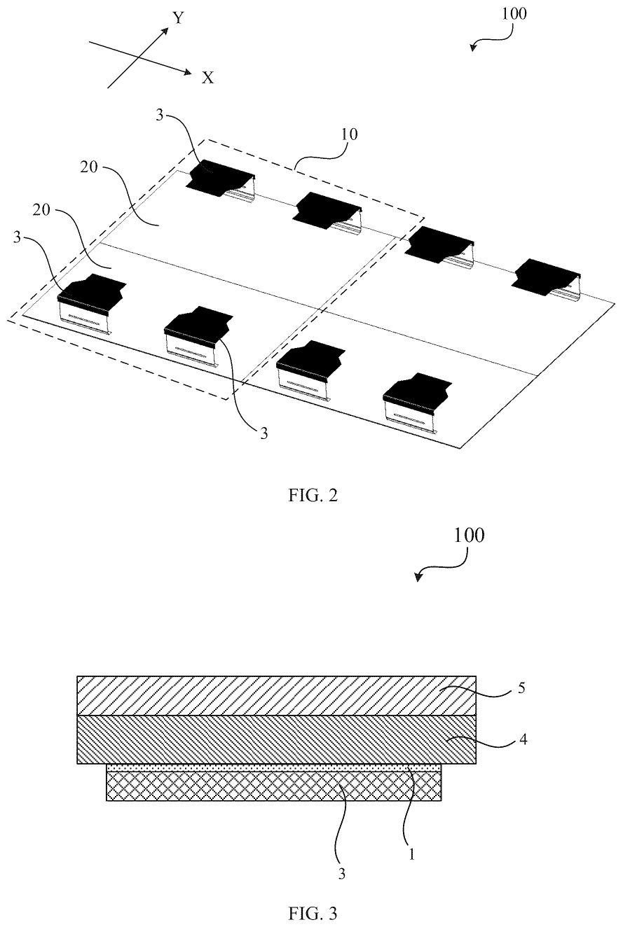

In one or more embodiments, FIG. 2 is a schematic structural diagram of another tiled display panel according to an embodiment of the present application. On the basis of the above-described embodiments, referring to FIG. 2, the tiled display panel 100 provided in this embodiment includes at least two tiled units 10, adjacent tiled units 10 are tiled in the second direction X, and the second direction X intersects with the first direction Y.

With the arrangement, the binding portions 1 at two ends of the at least two tiled units 10 tiled in the second direction X are configured to bind the chip on film 3, and the tiled display panel 100 binds the chip on film 3 by the binding portions 1 located at two ends of each tiled unit 10, thereby reducing the driving difficulty of the at least two tiled units 10 and further improving the display effect of the tiled display panel 100.

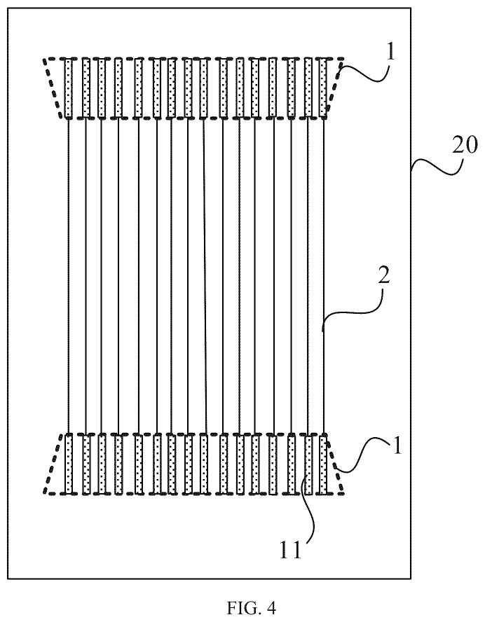

In one or more embodiments, FIG. 3 is a schematic sectional view taken along an AA′ direction of a tiled display panel of FIG. 1 according to an embodiment of the present application. On the basis of the above-described embodiments, referring to FIG. 3, the sub-display panel 20 of the tiled display panel 100 provided in this embodiment may further include a substrate 4 and a display portion 5 disposed on a side of the substrate 4. The binding portion 1 is disposed on a side of the substrate 4 facing away from the display portion 5. The signal line 2 connects the binding portions 1 located at the two ends of the sub-display panel 20 and extends to the display portion 5.

With the arrangement, the binding portion 1 is located on a non-light-emitting side of the sub-display panel 20, which facilitates the improvement of the screen-to-body ratio of the tiled display panel 100. The signal line 2 connects the binding portions 1 located at the two ends of the sub-display panels 20 and extends to the display portion 5. With the arrangement, after the multiple sub-display panels 20 are tiled in the same order, the chip on film 3 is bound to the binding portions 1 located at two ends of the tiled unit 10, and the drive signal on the chip on film 3 may be transmitted to the display portion 5 through the signal line 2 to drive the display portion 5 to display the screen, thereby further lowering the display driving difficulty of the tiled display panel 100.

In one or more embodiments, FIG. 4 is a schematic structural diagram of yet another tiled display panel according to an embodiment of the present application. On the basis of the above-described embodiments, in conjunction with FIGS. 3 and 4, the binding portion 1 of the tiled display panel 100 provided in this embodiment includes at least one binding terminal 11. The chip on film 3 is connected to the signal line 2 through the binding terminal 11. The chip on film 3 is configured to provide a display signal to the display portion 5 through the binding terminal 11 and the signal line 2.

The binding terminal 11, i.e., the gold finger, may bind the chip on film 3 to the binding terminal 11 by solder and the like. Since a width of the binding terminal 11 is greater than a width of the signal line 2, thereby facilitating increasing the reliability of the connection between the binding terminal 11 and the chip on film 3, further improving the reliability of the signal transmission of the tiled display panel 100, and further improving the display effect of the display panel.

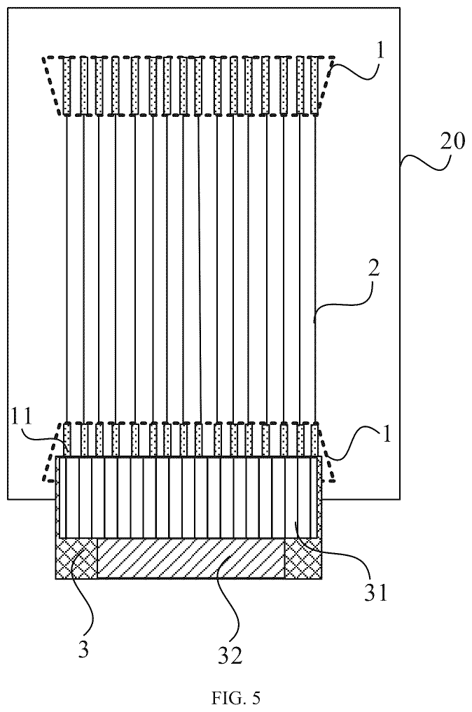

In one or more embodiments, FIG. 5 is a schematic structural diagram of yet another tiled display panel according to an embodiment of the present application. On the basis of the above-described embodiments, in conjunction with FIGS. 3 and 5, the chip on film 3 of the tiled display panel 100 provided in this embodiment may include a flexible printed circuit 31 and a driver chip 32 disposed on the flexible printed circuit 31. One end of the flexible printed circuit 31 is connected to the driver chip 32, and the other end of the flexible printed circuit 31 is connected to the binding terminal 11 of the binding portion 1.

The flexible printed circuit 31 includes multiple flexible signal lines 2. The flexible printed circuit 31 is configured to connect the driver chip 32 to the binding terminal 11, so that the drive signal outputted by the driver chip 32 may be transmitted to the binding terminal 11 via the flexible printed circuit 31 and then be transmitted to the display portion 5 via the flexible signal line 2, to drive the tiled display panel 100 to display pictures. On the other hand, the flexible printed circuit 31 is configured to bend the flexible printed circuit 31 to a corresponding position, to increase the screen ratio of the tiled display panel 100 and further improve the display effect of the tiled display panel 100.

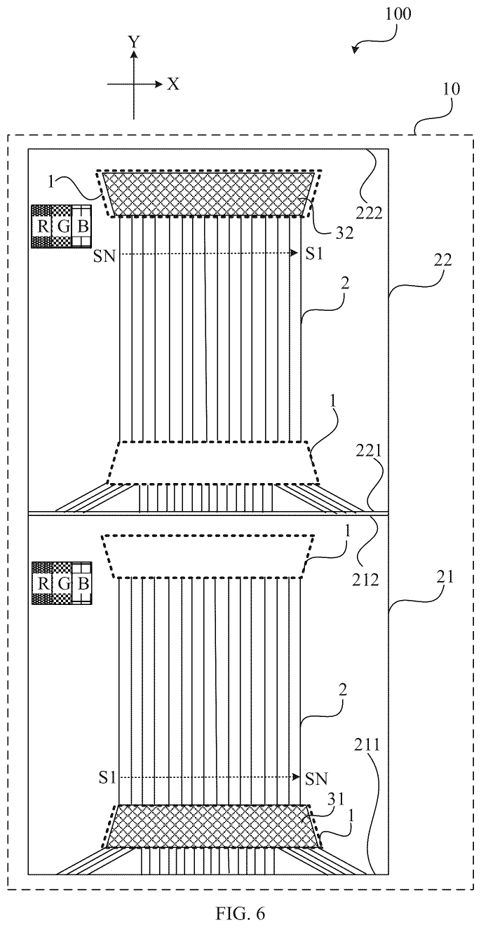

In one or more embodiments, FIG. 6 is a schematic structural diagram of yet another tiled display panel according to an embodiment of the present application. On the basis of the above-described embodiments, referring to FIG. 6, the tiled unit 10 of the tiled display panel 100 provided in this embodiment includes a first sub-display panel 21 and a second sub-display panel 22. The chip on film 3 includes a first chip on film 31 and a second chip on film 32. In the first direction Y, the first sub-display panel 21 includes a first end 211 and a second end 212 disposed opposite to each other, and the second sub-display panel 22 includes a third end 221 and a fourth end 222 disposed opposite to each other. The second end 212 of the first sub-display panel 21 is tiled with the third end 221 of the second sub-display panel 22. A binding portion 1 located at the first end 211 of the first sub-display panel 21 is configured to bind the first chip on film 31, and a binding portion 1 located at the fourth end 222 of the second sub-display panel 22 is configured to bind the second chip on film 32.

With the arrangement, neither the first sub-display panel 21 nor the second sub-display panel 22 needs to be rotated, a scanning direction of the first sub-display panel 21 is consistent with a scanning direction of the second sub-display panel 22, so that a pixel arrangement order of the first sub-display panel 21 is consistent with a pixel arrangement order of the second sub-display panel 22, thereby further reducing the driving difficulty of the tiled display panel.

In one or more embodiments, on the basis of the above-described embodiments, with continued reference to FIG. 6, the first chip on film 31 of the tiled display panel 100 provided in this embodiment is bound in the second direction X, the second chip on film 32 of the tiled display panel 100 provided in this embodiment is bound in an opposite direction of the second direction X, and a scanning direction of the first chip on film 31 is the same as a scanning direction of the second chip on film 32.

With the arrangement, the driving order of the signal lines of the first chip on film 31 may be sequentially driven from S1 to SN, and the driving order of the signal lines of the second chip on film 32 may be sequentially driven from SN to S1, whereby the scanning direction of the first sub-display panel 21 is consistent with the scanning direction of the second sub-display panel 22, that is, they are driven in the second direction X.

In one or more embodiments, on the basis of the above-described embodiments, with continued reference to FIGS. 2, 5, and 6, in the tiled display panel 100 provided in this embodiment, the number of binding portions 1 disposed at the first end 211 is the same as the number of binding portions 1 disposed at the second end 212; and/or, the number of binding portions 1 disposed at the third end 221 is the same as the number of binding portions 1 disposed at the fourth end 222; and/or, in the same tiled unit 10, the number of the binding portions 1 of the first sub-display panel 21 is the same as the number of the binding portions 1 of the second sub-display panel 22.

The number of binding portions 1 at the first end 211 is disposed to be the same as the number of binding portions 1 at the second end 212, thereby facilitating the connection between the binding portion 1 located at the first end 211 and the binding portion 1 located at the second end 212 through the signal line. The number of binding portions 1 disposed at the third end 221 is the same as the number of binding portions 1 disposed at the fourth end 222, thereby facilitating the connection between the binding portion 1 located at the third end 221 and the binding portion 1 located at the fourth end 222 through the signal line.

In the same tiled unit 10, the number of binding portions 1 of the first sub-display panel 21 is the same as the number of binding portions 1 of the second sub-display panel 22, whereby the first sub-display panel 21 and the second sub-display panel 22 of the same tiled unit 10 are driven in the same driving manner, so that driving effects of the first sub-display panel 21 and the second sub-display panel 22 of the tiled unit 10 are as consistent as possible, the display effects of the tiled unit 10 are as consistent as possible, and the display effect of the tiled display panel 100 is improved.

In one or more embodiments, on the basis of the above-described embodiments, with continued reference to FIG. 6, pixels on two sub-display panels 20 of the same tiled unit 10 are arranged in the same manner.

With the arrangement, the manufacturing cost of the tiled display panel 100 can be reduced, so that the display arrangement of the sub-display panels 20 of the tiled display panel 100 are all the same. On the other hand, a distal end of the first sub-display panel 21 is disposed to face a distal end of the second sub-display panel 22 when tiled, to solve the problem that the distal end of the first sub-display panel 21 faces a proximal end of the second sub-display panel 22 when tiled, whereby the transition uniformity of the display picture at the tiled position of the tiled display panel 100 is further improved, so that the first sub-display panel 21 and the second sub-display panel 22 have the same transferring method, the manufacturing difficulty of the tiled display panel 100 is further reduced, and thus the display effect of the tiled display panel 100 is improved.

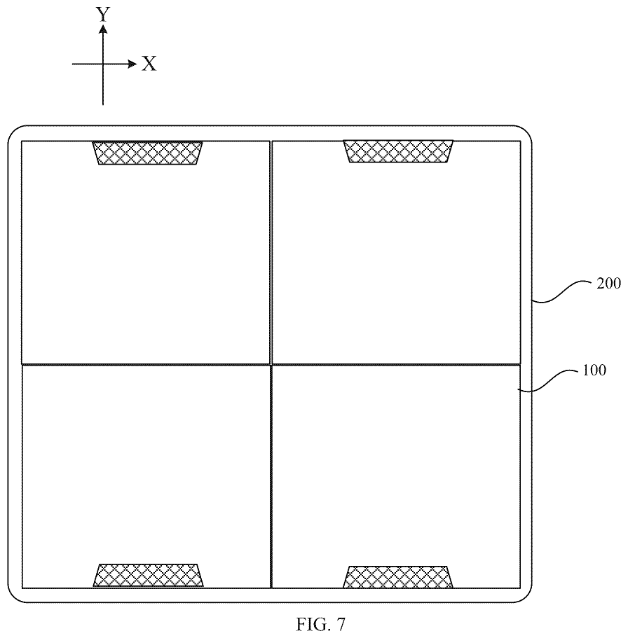

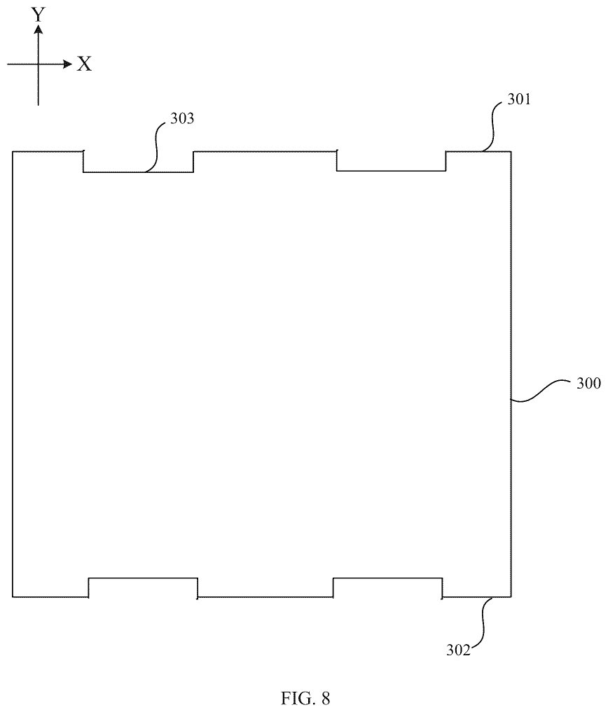

FIG. 7 is a schematic structural diagram of a display device according to an embodiment of the present application, and FIG. 8 is a schematic structural diagram of a glass substrate of a display device according to an embodiment of the present application. On the basis of the above-described embodiments, in conjunction with FIGS. 7 and 8, the display device 200 provided in this embodiment includes the tiled display panel 100 proposed in any of the above embodiments. The display device may further include a glass substrate 300. In the first direction Y, the glass substrate 300 includes a first edge 301 and a second edge 302. Each of the first edge 301 of the glass substrate 300 and the second edge 302 of the glass substrate 300 includes an open slot 303. The chip on film 3 is disposed within the open slot 303.

The display device 200 provided in this embodiment includes the tiled display panel 100 proposed in any of the above embodiments, which will not be repeated herein. The display device 200 provided in the embodiments of the present application may include terminals such as a cell phone, a tablet computer, and a wearable device.

It is to be understood that various forms of the flows shown above may be used with reordering, adding, or deleting steps. For example, the steps recited in the present application may be executed in parallel, sequentially or in different orders.

What is claimed is:

1. A tiled display panel, comprising:
at least one tiled unit, wherein each of the at least one tiled unit comprises two sub-display panels tiled in a first direction;
each of the two sub-display panels comprises:
at least two binding portions respectively located at two ends of a same sub-display panel in the first direction; and
at least one signal line configured to connect binding portions located at the two ends of the same sub-display panel; and
wherein binding portions located at two ends of each of the at least one tiled unit in the first direction are configured to bind a chip on film.

2. The tiled display panel of claim 1, wherein in a case where the tiled display panel comprises at least two tiled units, adjacent tiled units among the at least two tiled units are tiled in a second direction, and the second direction intersects with the first direction.

3. The tiled display panel of claim 1, wherein each of the two sub-display panels further comprises:
a substrate; and
a display portion disposed on a side of the substrate;
wherein the at least two binding portions are disposed on a side of the substrate facing away from the display portion; and
the at least one signal line connects binding portions located at the two ends of a same sub-display panel.

4. The tiled display panel of claim 3, wherein the at least one signal line extends to the display portion through binding portions.

5. The tiled display panel of claim 4, wherein each of the at least two binding portions comprises at least one binding terminal; and
the chip on film is connected to the at least one signal line through the at least one binding terminal, and the chip on film is configured to provide a display signal to the display portion through the at least one binding terminal and the at least one signal line.

6. The tiled display panel of claim 5, wherein a width of each of the at least one binding terminal is greater than a width of a signal line corresponding to the each of the at least one binding terminal.

7. The tiled display panel of claim 5, wherein the chip on film comprises:
a flexible printed circuit and a driver chip disposed on the flexible printed circuit; and
one end of the flexible printed circuit is connected to the driver chip, and another end of the flexible printed circuit is connected to a binding terminal of a binding portion configured to bind the chip on film.

8. The tiled display panel of claim 1, wherein each of the at least one tiled unit comprises a first sub-display panel and a second sub-display panel;
the chip on film comprises a first chip on film and a second chip on film;
in the first direction, the first sub-display panel comprises a first end and a second end disposed opposite to each other, the second sub-display panel comprises a third end and a fourth end disposed opposite to each other;
the second end of the first sub-display panel is tiled with the third end of the second sub-display panel; and
a binding portion located at the first end of the first sub-display panel is configured to bind the first chip on film, and a binding portion located at the fourth end of the second sub-display panel is configured to bind the second chip on film.

9. The tiled display panel of claim 8, wherein the first chip on film is bound in the second direction;
the second chip on film is bound in a direction opposite to the second direction; and
a scanning direction of the first chip on film is same as a scanning direction of the second chip on film.

10. The tiled display panel of claim 8, wherein a number of binding portions disposed at the first end is equal to a number of binding portions disposed at the second end.

11. The tiled display panel of claim 8, wherein a number of binding portions disposed at the third end is equal to a number of binding portions disposed at the fourth end.

12. The tiled display panel of claim 8, wherein in a same tiled unit, a number of binding portions of the first sub-display panel is equal to a number of binding portions of the second sub-display panel.

13. The tiled display panel of claim 8, wherein a number of binding portions disposed at the first end is equal to a number of binding portions disposed at the second end; and
a number of binding portions disposed at the third end is equal to a number of binding portions disposed at the fourth end.

14. The tiled display panel of claim 8, wherein a number of binding portions disposed at the first end is equal to a number of binding portions disposed at the second end;
in a same tiled unit, a number of binding portions of the first sub-display panel is equal to a number of binding portions of the second sub-display panel.

15. The tiled display panel of claim 8, wherein a number of binding portions disposed at the third end is equal to a number of binding portions disposed at the fourth end; and
in a same tiled unit, a number of binding portions of the first sub-display panel is equal to a number of binding portions of the second sub-display panel.

16. The tiled display panel of claim 8, wherein a number of binding portions disposed at the first end is equal to a number of binding portions disposed at the second end;
a number of binding portions disposed at the third end is equal to a number of binding portions disposed at the fourth end; and
in a same tiled unit, a number of binding portions of the first sub-display panel is equal to a number of binding portions of the second sub-display panel.

17. The tiled display panel of claim 2, wherein in the second direction, pixels on two sub-display panels of a same tiled unit are arranged in a same manner.

18. A display device, comprising the tiled display panel of claim 1, wherein the display device further comprises a substrate, the substrate comprises an open slot, and the chip on film is disposed within the open slot.

19. The display device of claim 18, wherein the substrate is a glass substrate.

20. The display device of claim 19, wherein open slots are disposed on a first edge and a second edge of the glass substrate in the first direction.
